(19) United States
(12) Patent Application Publication
(10) Pub. No.: US 2026/0255691 A1
(43) Pub. Date: Aug. 27, 2026

(54) SEMICONDUCTOR DEVICE

(71) Applicant: Vanguard International Semiconductor Corporation, Hsinchu (TW)

(72) Inventors: Yeh-Jen HUANG, Hsinchu City (TW); Jian-Hsing LEE, Hsinchu City (TW); Li-Yang HONG, Taoyuan City (TW); Yeh-Ning JOU, Hsinchu City (TW)

(73) Assignee: Vanguard International Semiconductor Corporation, Hsinchu (TW)

(21) Appl. No.: 19/059,418

(22) Filed: Feb. 21, 2025

(51) Int. Cl. H10D 89/60

(52) U.S. Cl. CPC H10D 89/815

(57) ABSTRACT

A semiconductor device is provided. The semiconductor device includes a substrate and drain contacts. The substrate has an active region. The active region includes a gate active region, a source active region and a drain active region. The source active region and the drain active region are located on opposite sides of the gate active region. The drain active region includes drain active segments that are spaced apart from each other. The drain contacts are disposed on a portion of the drain active segments. The number of drain active segments is equal to a first number, the number of drain contacts is equal to a second number, and the first number is not equal to the second number.

### BACKGROUND OF THE INVENTION

### Field of the Invention

The present invention relates to a semiconductor device, and in particular to a semiconductor device having electrostatic protection capability.

### Description of the Related Art

In order to prevent integrated circuits from being damaged by electrostatic discharge (ESD) during manufacturing, as well as during operation, they are usually equipped with an electrostatic discharge protection component. The electrostatic discharge protection component provides a current path for electrostatic discharge to stop the current from flowing into an internal circuit and thereby causing damage to the integrated circuits. Generally, the electrostatic discharge protection component is turned off under the normal operation of the integrated circuits and turned on during an electrostatic discharge event.

Since no component can be turned on quicker than an initial-on device, a conventional electrostatic discharge protection component cannot effectively protect an initial-on device. In addition, for the electrostatic discharge protection of ultra-high voltage (UHV) devices, adding electrostatic discharge protection components will increase the layout area of the UHV devices, which is not conducive to reducing the size of UHV devices.

### BRIEF SUMMARY OF THE INVENTION

An embodiment of the disclosure provides a semiconductor device. The semiconductor device includes a substrate and drain contacts. The substrate has an active region. The active region includes a gate active region, a source active region and a drain active region. The source active region and the drain active region are located on opposite sides of the gate active region. The drain active region includes drain active segments that are spaced apart from each other. The drain contacts are disposed on the drain active segments. The number of drain active segments is equal to a first number. The number of drain contacts is equal to a second number. The first number is not equal to the second number.

### BRIEF DESCRIPTION OF THE DRAWINGS

The present invention can be more fully understood by reading the subsequent detailed description and examples with references made to the accompanying drawings, wherein:

FIG. 1 is a schematic top view of a semiconductor device in accordance with some embodiments of the disclosure;

FIG. 2 is a schematic cross-sectional view along the line A-A′ of the semiconductor device in FIG. 1 in accordance with some embodiments of the disclosure;

FIGS. 3A, 3B, 3C, 3D, 3E, 3F, 3G, and 3H are enlarged top views of a portion of a drain active region of a semiconductor device in accordance with some embodiments of the disclosure, showing various embodiments of drain active segments and the correspondence between the drain active segments and drain contacts;

FIGS. 4A, 4B, and 4C are enlarged top views of a portion of the drain active region and drain contacts of a semiconductor device in accordance with some embodiments of the disclosure, showing the correspondence between the drain active segments and the drain contacts;

FIG. 5 is a schematic top view of a semiconductor device in accordance with some embodiments of the disclosure;

FIG. 6 is a schematic top view of a semiconductor device in accordance with some embodiments of the disclosure; and

FIG. 7 is a schematic top view of a semiconductor device in accordance with some embodiments of the disclosure.

### DETAILED DESCRIPTION OF THE INVENTION

The embodiments of the present disclosure are described fully hereinafter with reference to the accompanying drawings. It should be noted, however, that the present disclosure is not limited to the following exemplary embodiments, and may be implemented in various forms. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to improving the electrostatic discharge (ESD) protection capabilities of initial-on semiconductor devices. In some embodiments of the present disclosure, the drain region (drain active region) is divided into a plurality of drain segments (drain active segments) that are laterally spaced from each other. In addition, a plurality of drain contacts is provided to be electrically connected to the drain region. Each of drain segments corresponds to at least one drain contact. These drain contacts are electrically connected to a drain electrode in parallel for spreading the ESD current to the entire drain region, thereby improving the ESD protection capability of the semiconductor device itself without increasing the layout area of the semiconductor device.

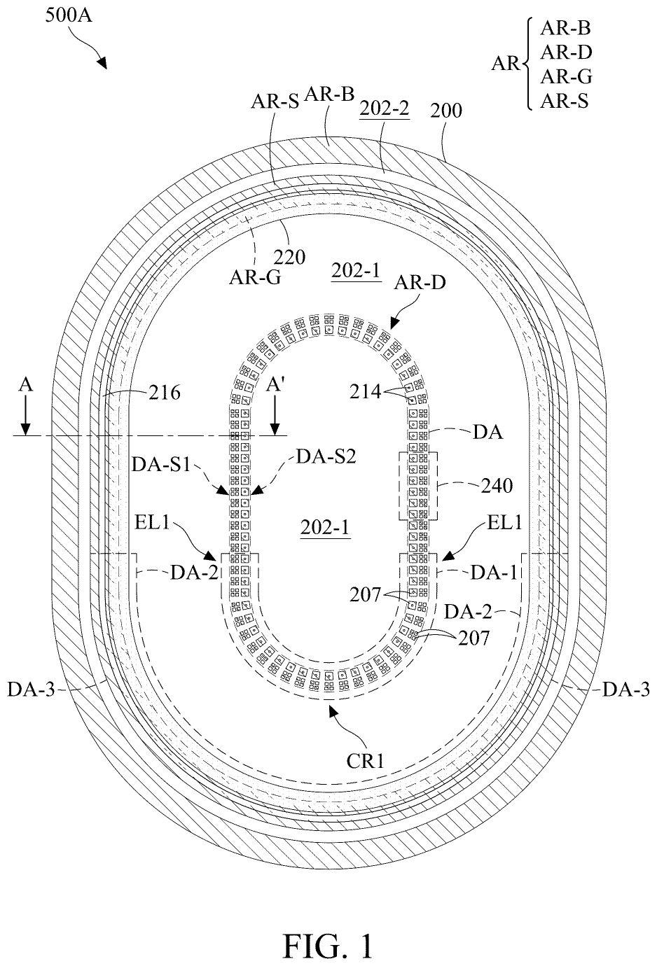

FIG. 1 is a top schematic view (or a schematic layout) of a semiconductor device 500A in accordance with some embodiments of the disclosure. In some embodiments, the semiconductor device 500A is a depletion-mode metal oxide semiconductor field effect transistor (D-mode MOSFET), which is an initial-on semiconductor device.

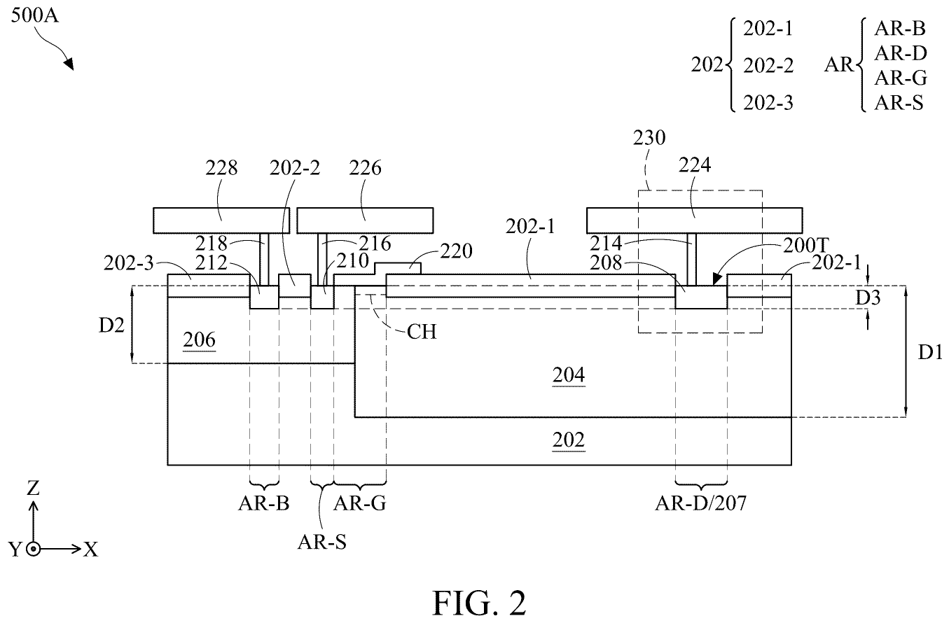

The semiconductor device 500A includes substrate 200, isolation features 202-1 and 202-2, an active region AR, a gate electrode 220, a source contact 216, and drain contacts 214. For illustration, FIG. 1 only shows the above features, the remaining features can be seen in the schematic cross-section of FIG. 2, which is taken along the line A-A′ of FIG. 1.

As shown in FIGS. 1 and 2, the substrate 200 may be a semiconductor substrate. The semiconductor substrate includes an elementary semiconductor including silicon (Si), germanium (Ge), etc.; a compound semiconductor including gallium nitride (GaN), silicon carbide (SiC), gallium arsenide (GaAs), gallium phosphide (GaP), indium phosphide (InP), indium arsenide (InAs), indium antimonide (InSb), etc.; an alloy semiconductor including SiGe, GaAsP, AlInAs, AlGaAs, GaInAs, GaInP, GaInAsP, or a combination thereof. In addition, the substrate 200 may also be a semiconductor on insulator (SOI). In some embodiments, the substrate 200 has a first conductivity type, such as P-type. For example, the substrate 200 may be a p-type silicon substrate (PSUB).

The semiconductor device 500A also includes a first well region 204 and a second well region 206 located in the substrate 200. The first well region 204 and the second well region 206 both extend from the top surface 200T of the substrate 200 into a portion of the substrate 200. The first well region 204 and the second well region 206 are arranged side by side and adjacent to each other along the X-axis direction (a lateral direction) that is substantially parallel to the top surface 200T of the substrate 200. In addition, the second well region 206 may surround the first well region 204. In some embodiments, the depth D1 of the first well region 204 along the Z-axis direction (a longitudinal direction) that is substantially perpendicular to the top surface 200T of the substrate 200 is greater than the depth D2 of the second well region 206 along the Z-axis direction. In other words, in the Z-axis direction, the bottom surface of the first well region 204 is below the bottom surface of the second well region 206. In some embodiments, the first well region 204 has a second conductivity type that is opposite to the first conductivity type, such as a high voltage n-type well region (HVNW). The second well region 206 has a first conductivity type, such as a P-type well region (PW).

In some embodiments, multiple ion implantation processes may be used to implant P-type and N-type dopants into the substrate 200 to form the first well region 204 and the second well region 206 respectively. In some embodiments, the N-type dopant may include phosphorus, arsenic, nitrogen, antimony, or a combination thereof. In some embodiments, the P-type dopant may include boron, gallium, aluminum, indium, boron trifluoride ions (BF3+), or a combination thereof.

The isolation features 202 (including the isolation features 202-1, 202-2, 202-3) are disposed in the substrate 200, and extend from the top surface 200T of the into a portion of the substrate 200. As shown in FIGS. 1 and 2, the isolation features 202 are used to define active regions AR (including a bulk active region AR-B, a drain active region AR-D, and a source active region AR-S). In detail, the isolation feature 202-1 may be disposed in a portion of the first well region 204 and be separated from an interface F1 between the first well region 204 and the second well region 206. The isolation feature 202-1 may surround the drain active region AR-D to define the drain active region AR-D. The isolation features 202-2, 202-3 may be disposed in a portion of the second well region 206 and spaced apart from each other along the X-axis direction (the lateral direction). In the Z-axis direction, the isolation feature 202-2 is located between the isolation features 202-1 and 202-3. Furthermore, the isolation feature 202-2 is separated from the isolation feature 202-1 and the interface F1 between the first well region 204 and the second well region 206. The isolation feature 202-2 may surround the isolation feature 202-1. The isolation feature 202-2 and the isolation feature 202-1 may define a gate active region AR-G and a source active region AR-S. The source active region AR-S is connected to and surrounds the gate active region AR-G. The gate active region AR-G and the source active region AR-S collectively surround the drain active region AR-D. The gate active region AR-G is closer to the interface F1 between the first well region 204 and the second well region 206 than the source active region AR-S. Moreover, the source active region AR-S and the drain active region AR-D are respectively located on opposite sides of the gate active region AR-G. The isolation feature 202-3 may be located outside the isolation feature 202-2 and may surround the isolation feature 202-2 (the isolation feature 202-3 is not shown in FIG. 1). The isolation feature 202-3 and the isolation feature 202-2 may define the bulk active region AR-B. The bulk active region AR-B may surround the gate active region AR-G, the source active region AR-S and the drain active region AR-D.

In some embodiments, the drain active region AR-D includes drain active segments 207 that are spaced apart from each other. In some embodiments, the drain active segment 207 includes a rectangular, circular, or oval shape. In this embodiment, the drain active segment 207 is, for example, a rectangular segment.

As shown in FIG. 1, the drain active region AR-D has a distribution region DA. In some embodiments, the top view shape of the distribution region DA of the drain active region AR-D may include a ring-shape (including a racetrack shape, an annular (circular-ring) shape, a square round-ring shape) or an interdigitated shape. The gate active region AR-G and the source active region AR-S are continuously distributed, and their top-view shapes may correspond to (the same as or are similar to) the top-view shape of the distribution region DA. In this embodiment, the distribution region DA of the drain active region AR-D may be in a racetrack shape. Furthermore, the distribution region DA of the drain active region AR-D may include a U-shaped region DA-1. The U-shaped region DA-1 has a rounded corner portion CR1 and linear extension portions EL1 connected to the rounded corner portion CR1. In this embodiment, the gate active region AR-G may be racetrack-shaped, and may have a U-shaped region DA-2. Furthermore, the U-shaped region DA-2 is disposed corresponding to the U-shaped region DA-1. For example, the U-shaped region DA-2 is located outside and arranged parallel to the U-shaped region DA-1. In this embodiment, the source active region AR-S may be racetrack-shaped, and may have a U-shaped region DA-3. Furthermore, the U-shaped region DA-3 is disposed corresponding to the U-shaped region DA-2. For example, the U-shaped region DA-3 is located outside and arranged parallel to the U-shaped region DA-2.

In some embodiments, the isolation feature 202 is a field oxide (FOX) formed by a local oxidation of silicon (LOCOS) process, a shallow trench isolation (STI) structure formed by a deposition process, or other suitable isolation structures. In some embodiments, the isolation feature 202 is formed using a thermal oxidation process including a dry oxidation process, a wet oxidation process, or other suitable thermal oxidation processes.

The semiconductor device 500A further includes a drain doped region 208 located on the first well region 204, and a source doped region 210 and a bulk doped region 212 located on the second well region 206. The drain doped region 208, the source doped region 210 and the source active region AR-S extend from the top surface 200T of the substrate 200 into a portion of the substrate 200. The drain doped region 208 is located in the drain active region AR-D, adjacent to and surrounded by the isolation feature 202-1. The source doped region 210 is located in the source active region AR-S, adjacent to and surrounded by the isolation feature 202-2. Also, the source doped region 210 may be separated from isolation feature 202-1. The bulk doped region 212 is located in the bulk active region AR-B, adjacent to the isolation features 202-2 and 202-3 and surrounded by the isolation feature 202-3. Also, the bulk doped region 212 may surround the isolation feature 202-2.

In some embodiments, the drain doped region 208, the source doped region 210 and the bulk doped region 212 have the same depth D3 along the Z-axis direction. The drain doped region 208 may have a higher impurity concentration than the first well region 204. The bulk doped region 212 may have a higher impurity concentration than the second well region 206. Both the drain doped region 208 and the source doped region 210 have a second conductivity type, such as an N-type heavily doped region (N+). The bulk doped region 212 has a first conductivity type, such as a P-type heavily doped region (P+).

In some embodiments, multiple ion implantation processes may be used to respectively implant P-type and N-type dopants into the substrate 200 to form the drain doped region 208, the source doped region 210 and the bulk doped region 212. In some embodiments, the N-type dopant may include phosphorus, arsenic, nitrogen, antimony, or a combination thereof. In some embodiments, the P-type dopant may include boron, gallium, aluminum, indium, boron trifluoride ions (BF3+), or a combination thereof. In some embodiments, the drain doped region 208 and the source doped region 210 may be simultaneously formed by the same ion implantation process or may be respectively formed by different ion implantation processes.

The semiconductor device 500A further includes a gate electrode 220 located on the gate active region AR-G of the substrate 200. The gate electrode 220 is disposed on and formed across the first well region 204 and the second well region 206. A portion of the gate electrode 220 extends from a side surface of the isolation feature 202-1 close to the interface F1 to the top surface of the isolation feature 202-1. In addition, the other portion of the gate electrode 220 is adjacent to the source doped region 210. The drain doped region 208 and the gate electrode 220 are separated by a distance along the X-axis direction. The isolation feature 202-1 is located between the drain doped region 208 and the gate electrode 220. In the X-axis direction, the distance between the drain doped region 208 and the gate electrode 220 is longer than the distance between the source doped region 210 and the gate electrode 220. The top view shape of the gate electrode 220 may correspond to the top view shape of the distribution region DA. In some embodiments, the gate electrode 220 includes a gate dielectric layer (not shown) disposed on the substrate 200, a gate electrode layer (not shown) disposed above the gate dielectric layer, a gate electrode layer (not shown) disposed on the gate dielectric layer, and gate spacers (not shown) disposed on the sidewalls of the dielectric layer and the gate electrode layer.

In some embodiments, the gate dielectric layer includes silicon oxide, silicon nitride, silicon oxynitride, high dielectric constant (high-k) materials, other suitable dielectric materials, and/or a combination thereof. The high dielectric constant materials are, for example, hafnium oxide, hafnium silicon oxide, hafnium silicon oxynitride, hafnium tantalum oxide, hafnium titanium oxide, hafnium zirconium oxide, zirconium oxide, aluminum oxide, hafnium dioxide-alumina alloy, and/or a combination thereof or the like. In some embodiments, the gate dielectric layer may be formed on the substrate 200 using an oxidation process, a deposition process, or other suitable processes. In some embodiments, the gate electrode layer includes polycrystalline silicon, amorphous silicon, metals (such as tungsten, titanium, aluminum, copper, molybdenum, nickel, platinum, other suitable metals, or a combination thereof), metal alloys, metal nitrides (such as tungsten nitride, molybdenum nitride, titanium nitride, tantalum nitride, other suitable metal nitrides, or combinations of the above), metal oxides (such as ruthenium oxide, indium tin oxide, other suitable metal oxides, or a combination thereof), other suitable materials, or a combination thereof. In some embodiments, dopants may be implanted into the gate electrode layer using in-situ doping. In some embodiments, the gate spacer includes silicon oxide, silicon nitride, silicon oxynitride, low dielectric constant (low-k) materials, other suitable dielectric materials, and/or a combination thereof. In some embodiments, the gate spacers may be formed on the sidewalls of the gate dielectric layer and the gate electrode layer using an oxidation process, a deposition process, or other suitable processes.

The semiconductor device 500A further includes drain contacts 214, a source contact 216, a bulk contact 218, a drain electrode 224, a source electrode 226, and a bulk electrode 228 located on substrate 200.

The drain contacts 214 of the semiconductor device 500A are disposed on a portion, but not all, of the drain active segments 207. In some embodiments, the drain contact 214 is disposed on the drain active segments 207 away from the gate active region AR-G, but not disposed on the drain active segments 207 close to the gate active region AR-G. In some embodiments, each of the drain active segments 207 far away from the gate active region AR-G may correspond to one drain contact 214. In addition, each of the drain active segments 207 close to the gate active region may correspond to zero drain contact 214 (the drain active segments 207 close to the gate active region are electrically floating). In some embodiments, the number of drain active segments 207 is equal to a first number, the number of drain contacts 214 is equal to a second number. The first number is not equal to the second number. For example, the first number is higher than the second number. In some embodiments, the drain contacts 214 are disposed on the second number of drain active segments 207, and the remaining drain active segments 207 are electrically floating.

In this embodiment, the distribution region DA of the drain active region AR-D is in the shape of a racetrack. The first side DA-S1 of the distribution region DA (or the first side DA-S1 of the U-shaped region DA-1) is located outside the racetrack-shaped distribution region DA. The second side DA-of the distribution region DA-S2 (or the second side DA-S2 of the U-shaped region DA-1) is located inside the racetrack-shaped distribution region DA.

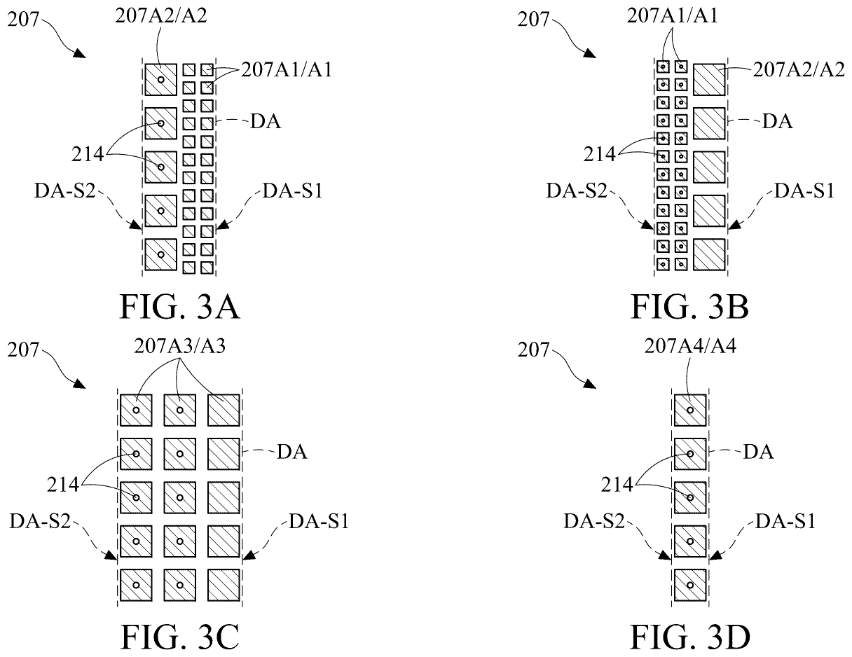

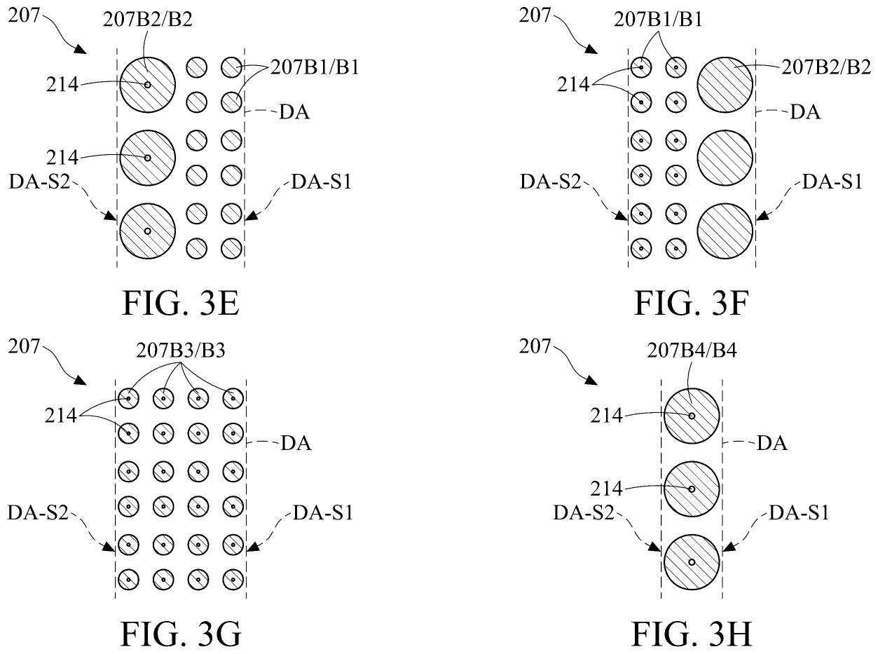

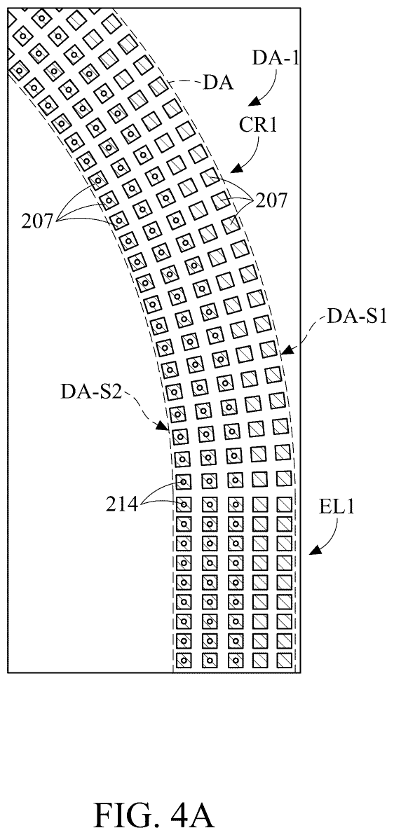

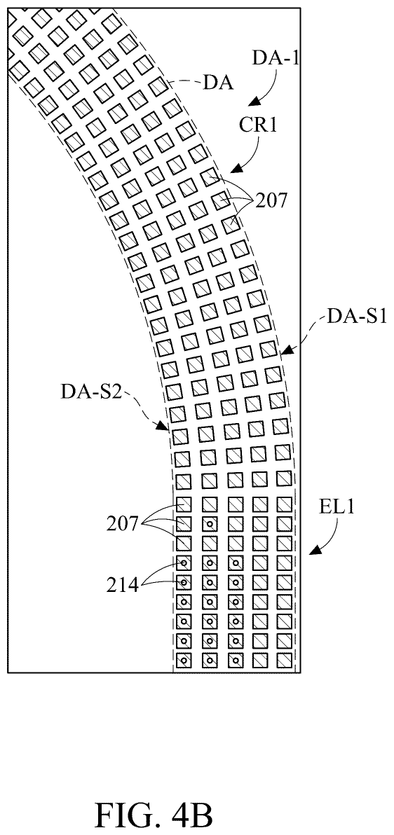

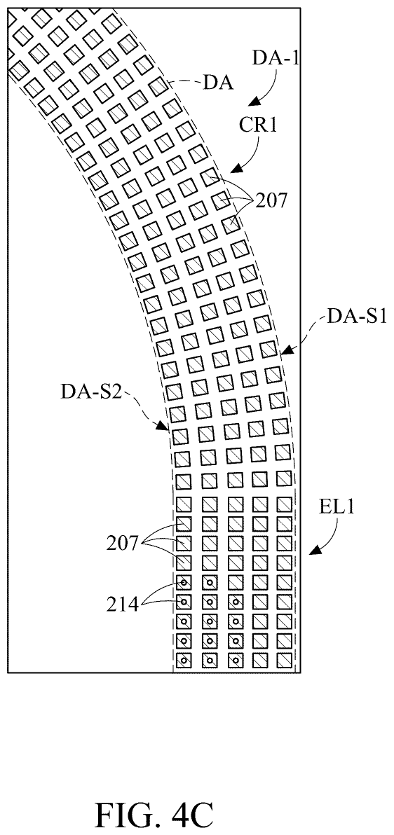

The distribution region DA (or the U-shaped region DA-1 of the distribution region DA) has a first side (the outer side) DA-S1 close to the gate active region AR-G and a second side (the inner side) DA-S2 far away from the gate active region AR-G. The first side (the outer side) DA-S1 and the second side (the inner side) DA-S2 are opposite to each other. The drain contacts 214 are disposed on the drain active segments 207 close to the second side (the inner side) DA-S2, but not disposed on the drain active segments 207 close to the first side (the outer side) DA-S1. In some embodiments, the drain contacts 214 are disposed on the drain active segments 207 of the U-shaped region DA-1 close to the rounded corner CR1 and the linear extension portion EL1 of the second side (the inner side) DA-S2. The drain contacts 214 and the aforementioned drain active segments 207 have a one-to-one correspondence. In order to make the drawing clear and easy to understand, FIG. 2 shows a simplified drawing of the drain active segment 207 (and the drain doped region 208) and the drain contact 214. The detailed correspondence between the drain active segment 207 (and the drain doped region 208) and the drain contact 214 in the area 230 of FIG. 2 may refer to the following descriptions of FIGS. 3A to 3H and 4A to 4C.

The drain electrode 224 is disposed on the substrate 200. The drain contact 214 may be electrically connected to drain electrode 224 in parallel. In some embodiments, the top view shape of the drain electrode 224 corresponds to the top view shape of the distribution region DA of the drain active region AR-D shown in FIG. 1. In this embodiment, the top view shape of the drain electrode 224 may be a racetrack shape. These drain active segments 207 and these drain contacts 214 are located within the area of the racetrack-shaped drain electrode 224.

As shown in FIGS. 1 and 2, at least one source contact 216 is disposed on the source active region AR-S of the substrate 200. In addition, the source contact 216 is electrically connected to the source doped region 210 of the source active region AR-S. In the layout from a top view shown in FIG. 1, the top view shape of the source contact 216 corresponds to the top view shape of the source active region AR-S. In this embodiment, the top view shape of the source active region AR-S and the source contact 216 may be a racetrack shape.

The source electrode 226 is disposed on the substrate 200 and is electrically connected to the source electrode 226. In some embodiments, the top view shape of the source electrode 226 corresponds to the top view shape of the source active region AR-S shown in FIG. 1. In this embodiment, the source electrode 226 may have a racetrack shape in the top view and surround the drain electrode 224. The racetrack-shaped source contact 216 is located within the area of the racetrack-shaped source contact 216.

As shown in FIG. 2, the bulk contact 218 is disposed on the bulk active region AR-B of the substrate 200. In addition, the bulk contact 218 is electrically connected to the bulk doped region 212 of the bulk active region AR-B. The bulk doped region 212 is electrically connected to the bulk electrode 228 disposed on the substrate 200 through the bulk contact 218. Furthermore, the source electrode 226 is located between the bulk electrode 228 and the drain electrode 224.

In some embodiments, the semiconductor device 500A is an N-channel depletion-mode metal oxide semiconductor field effect transistor. When no voltage is applied to the gate electrode 120, a N-type channel region CH between the source doped region 210 and the drain doped region 208 is turned on, i.e., the depletion-mode metal oxide semiconductor field effect transistor is an initial-on semiconductor device.

According to some embodiments of the disclosure, the drain active region AR-D of the semiconductor device 500A is divided into a plurality of drain active segments 207 laterally spaced apart from each other by the isolation feature 202-1. In the drain active region AR-D, only a portion of the drain doped regions 208 in the drain active segments 207 are electrically connected to the drain contacts 214. For example, each of the drain doped regions 208 in the drain active segments 207 that are far away from the gate active region AR-G (or the gate electrode 220) may correspond to and be electrically connected to a drain contact 214. The aforementioned drain doped regions 208 in the drain active segments 207 are electrically connected to the drain electrode 224 in parallel through the drain contacts 214. The drain doped region 208 in each of the drain active segments 207 may be regarded as a small resistor. When the electrostatic discharge (ESD) event occurs, the small resistor constructed by the drain doped region 208 in each of the above-mentioned drain active segments 207 can independently bears the electrostatic discharge (ESD) energy, and the electrostatic discharge (ESD) current flows into the drain doped region 208 in each of the drain active segments 207 evenly through each of the drain contacts 214, thereby spreading the electrostatic discharge (ESD) current to the drain doped region 208 in each of the drain active segments 207 to lower the potential of the entire drain doped regions 208. In addition, compared with the drain active segments 207 close to the gate active region AR-G (or the gate electrode 220), the drain active segments 207 far away from the gate active region AR-G (or the gate electrode 220) have a lower surface electric field. Therefore, when the electrostatic discharge event occurs, the above connection method may avoid the drain contacts 214 that are disposed on the outer drain active segments 207 (close to the first side DA-S1 of the distribution region DA) attacked by electrostatic discharge current and burned out. Therefore, the ability of the semiconductor device 500A of the present disclosure to withstand electrostatic discharge is improved to obtain better electrostatic discharge protection capability.

In addition, according to the embodiments of the present disclosure, the ESD protection function of the semiconductor device 500A is kept turn-on under normal operation, so that for the initial-on semiconductor devices, there is no problem of slow turn-on in the ESD protection component of the semiconductor device 500A. Moreover, in the embodiments of the present disclosure, the ESD protection component of the semiconductor device 500A is provided by the drain active segments 207 (and the drain doped regions 208 within). Therefore, the ESD protection component will not occupy the layout area of the semiconductor device, which is beneficial to the miniaturization of the size of the semiconductor device. Moreover, the semiconductor device of the present disclosure has the ESD protection capability by itself, which is beneficial to the application for ultra-high voltage (UHV) devices.

FIGS. 3A, 3B, 3C, 3D, 3E, 3F, 3G, and 3H are enlarged top views of the area 240 of the semiconductor device 500A in accordance with some embodiments of the disclosure in FIG. 1, showing various embodiments of drain active segments and the correspondence between the drain active segments and drain contacts. FIGS. 3A, 3B, 3C, and 3D use rectangular drain active segments 207 as an example, while FIGS. 3E, 3F, 3G, and 3H use circular drain active segments 207 as an example. The drain active segments 207 shown in FIGS. 3A to 3H may have other shapes and is not limited to the embodiments described herein.

As shown in FIG. 3A, the drain active segments 207 may include a plurality of rectangular drain active segments 207A1 and a plurality of rectangular drain active segments 207A2. The drain active segments 207A1 and 207A2 may be periodically arranged along the tangential direction and the normal direction of the distribution region DA. In this embodiment, the drain active segments 207A1 are disposed close to the first side (the outer side) DA-S1 of the distribution region DA. The drain active segments 207A2 are disposed close to the second side (the inner side) DA-S2 of the distribution region DA. Furthermore, the drain active segments 207A1 may surround the drain active segments 207A2. In this embodiment, the drain contacts 214 may be disposed on the drain active segments 207A2 but not on the drain active segments 207A1. In some embodiments, the area A1 of each of the drain active segments 207A1 is not equal to the area A2 of each of the drain active segments 207A2. For example. the area A1 of each of the drain active segments 207A1 is smaller than the area A2 of each of the drain active segments 207A2.

In the embodiment shown in FIG. 3B, the rectangular drain active segments 207A1 are disposed close to the second side (the inner side) DA-S2 of the distribution region DA. The rectangular drain active segments 207A2 are disposed close to the first side (the outer side) DA-S1 of the distribution region DA. Furthermore, the drain active segments 207A2 may surround the drain active segments 207A1. In this embodiment, the drain contacts 214 may be disposed on the drain active segments 207A1 but not disposed on the drain active segments 207A2.

In the embodiment shown in FIG. 3C, the drain active segment 207 may include a plurality of rectangular drain active segments 207A3. The drain active segments 207A3 may be periodically arranged along the tangential direction and the normal direction of the distribution region DA. In this embodiment, each of the drain active segments 207A3 has a uniform area A3. The drain contacts 214 may be disposed on the drain active segments 207A3 close to the second side (the inner side) DA-S2 of the distribution region DA but not disposed on the drain active segments 207A3 close to the first side (the outer side) DA-S1 of the distribution region DA.

In some embodiments shown in FIG. 3D, the drain active segments 207 may include a plurality of rectangular drain active segments 207A4. Each of the drain active segments 207A4 has a uniform area A4. In this embodiment, the area A4 of each of the drain active segments 207A4 is larger than the area A3 of each of the drain active segments 207A3 (FIG. 3C). Therefore, the drain active segments 207A4 may be periodically arranged only along the tangential direction of the distribution region DA. In this embodiment, the drain contacts 214 may be disposed on each drain active segment 207A4.

As shown in FIG. 3E, the drain active segments 207 may include a plurality of circular drain active segments 207B1 and a plurality of circular drain active segments 207B2. The drain active segments 207B1 and 207B2 may be periodically arranged along the tangential direction and the normal direction of the distribution region DA. In this embodiment, the drain active segments 207B1 are disposed close to the first side (the outer side) DA-S1 of the distribution region DA, and the drain active segment 207B2 is disposed close to the second side (the inner side) DA-S2 of the distribution region DA. Also, the drain active segments 207B1 may surround the drain active segments 207B2. In this embodiment, the drain contacts 214 (FIG. 1) may be disposed on the drain active segments 207B2 but not disposed on the drain active segments 207B1. In some embodiments, the area B1 of each of the drain active segments 207B1 is not equal to the area B2 of each of the drain active segments 207B2. For example. The area B1 of each of the drain active segments 207B1 is smaller than the area B2 of each of the drain active segments 207B2.

In some embodiments shown in FIG. 3F, the circular drain active segments 207B1 are disposed close to the second side (the inner side) DA-S2 of the distribution region DA, and the circular drain active segments 207B2 are disposed close to the first side (the outer side) DA-S1 of the distribution region DA. Also, the drain active segments 207B2 may surround the drain active segments 207B1. In this embodiment, the drain contacts 214 (FIG. 1) may be disposed on the drain active segments 207B1 but not disposed on the drain active segments 207B2.

In some embodiments shown in FIG. 3G, the drain active segment 207 may include a plurality of circular drain active segments 207B3. The drain active segments 207B3 may be periodically arranged along the tangential direction and the normal direction of the distribution region DA. In this embodiment, each of the drain active segments 207B3 has a uniform area B3. The drain contacts 214 (FIG. 1) may be disposed on the drain active segments 207B3 close to the second side (the inner side) DA-S2 of the distribution region DA but not disposed on the drain active segment 207B3 close to the first side (the outer side) DA-S1 of the distribution region DA.

In some embodiments shown in FIG. 3H, the drain active segment 207 may include a plurality of circular drain active segments 207B4. Each drain active segment 207B4 has a uniform area B4. In this embodiment, the area B4 of each drain active segment 207B4 may be larger than the area B3 of each drain active segment 207B3 (FIG. 3G). Therefore, the drain active segments 207B4 may be periodically arranged only along the tangential direction of the distribution region DA. In this embodiment, a drain contact 214 (FIG. 1) may be disposed on each drain active segment 207B4.

In some embodiments, since the corners (rounded corners or sharp corners) of the drain active region distribution region has a large surface electric field. The drain contacts may avoid being disposed on the drain active segments located at the corner of the drain active region distribution region in order to further improve the electrostatic discharge (ESD) protection capability.

FIGS. 4A, 4B, and 4C are enlarged top views of the drain active segments 207 and the drain contacts 214 in a portion of the U-shaped region DA-1 of the semiconductor device 500A in accordance with some embodiments of the disclosure, showing the correspondence between the drain active U-shaped region DA-1 of the semiconductor device 500A. The shape and arrangement of the drain active segments 207 shown in FIGS. 4A, 4B and 4C are similar to the shape and arrangement of the drain active segments 207A3 shown in FIG. 3C. However, the shape and arrangement of the drain active segments 207 shown in FIGS. 4A, 4B, and 4C may also be similar to the shapes and arrangements of the drain active segments 207A1, 207A2, 207A4, 207B1, 207B2, 207B3, and 207B4 shown in FIGS. 3A, 3B, 3D, 3E, 3F, 3G, and 3H, and will not repeat it here.

As shown in FIG. 4A, the drain contacts 214 may be disposed on the drain active segments 207 of the rounded corner CR1 and the linear extension portion EL1 of the U-shaped region DA-1.

As shown in FIG. 4B, in other embodiments, the drain contacts 214 may be disposed on the drain active segments 207 of the straight extension portion EL1, but not disposed on the drain active segments 207 of the rounded corner portion CR1. Compared with FIG. 4A, the position of the drain contacts 214 shown in FIG. 4B may further improve the electrostatic discharge (ESD) protection capability.

As shown in FIG. 4C, in other embodiments, the drain contact 214 may be disposed on the drain active segments 207 of the linear extension portion EL1 away from the rounded corner CR1. Compared with FIG. 4B, the position of the drain contacts 214 shown in FIG. 4C linear extension EL further improve the electrostatic discharge (ESD) protection capability.

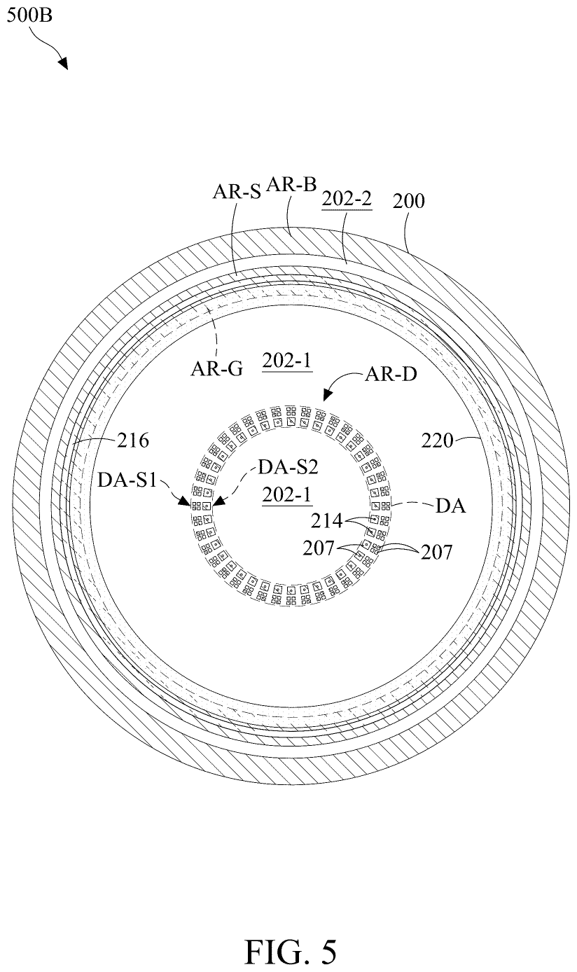

FIG. 5 is a schematic top view of a semiconductor device 500B in accordance with some embodiments of the disclosure, in which the reference numbers the same or similar to those in FIG. 1 denote the same or similar elements. As shown in FIG. 5, at least one of the differences between the semiconductor device 500B and the semiconductor device 500A is that the distribution region DA of the drain active region AR-D of the semiconductor device 500B may be annular shaped (or circular-ring shaped). Furthermore, the top view shapes of the gate active region AR-G, the source active region AR-S and the gate electrode 220 of the semiconductor device 500B may correspond to the top view shape (annular shape) of the distribution region DA.

In this embodiment, the distribution region DA of the drain active region AR-D is annular shaped. The first side DA-S1 of the distribution region DA (or the first side DA-S1 of the U-shaped region DA-1) is located outside the annular distribution region DA, and the second side DA-S2 of the distribution region DA (or the second side DA-S2 of the U-shaped region DA-1) is located inside the annular distribution region DA.

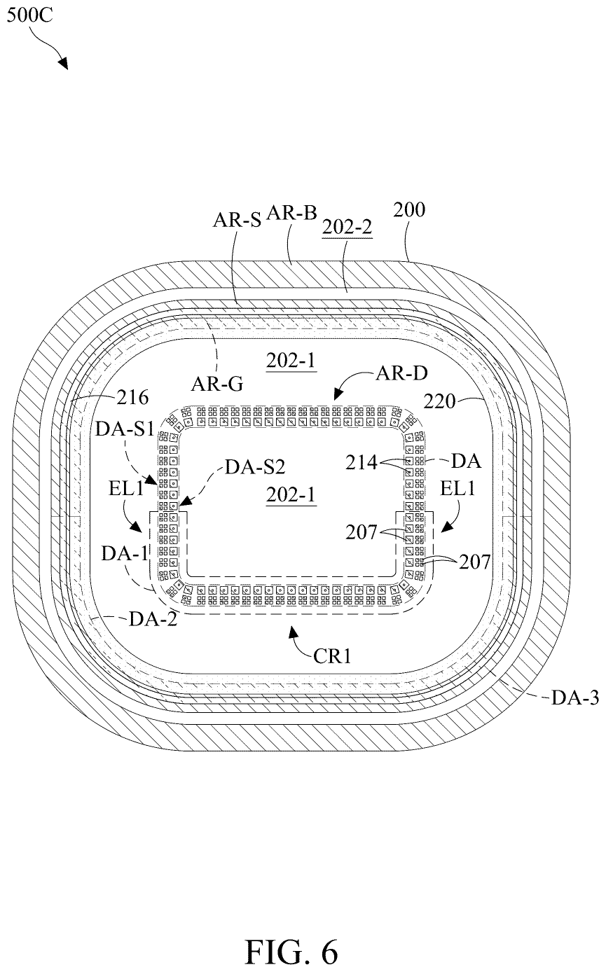

FIG. 6 is a schematic top view of a semiconductor device 500C in accordance with some embodiments of the disclosure, in which the reference numbers the same or similar to those in FIG. 1 denote the same or similar elements. As shown in FIG. 6, at least one of the differences between the semiconductor device 500C and the semiconductor device 500A is that the distribution region DA of the drain active region AR-D of the semiconductor device 500C may be square round-ring shaped. Furthermore, the top view shapes of the gate active region AR-G, the source active region AR-S and the gate electrode 220 of the semiconductor device 500C may be the same or similar to the top view shape (square round-ring shape) of the distribution region DA.

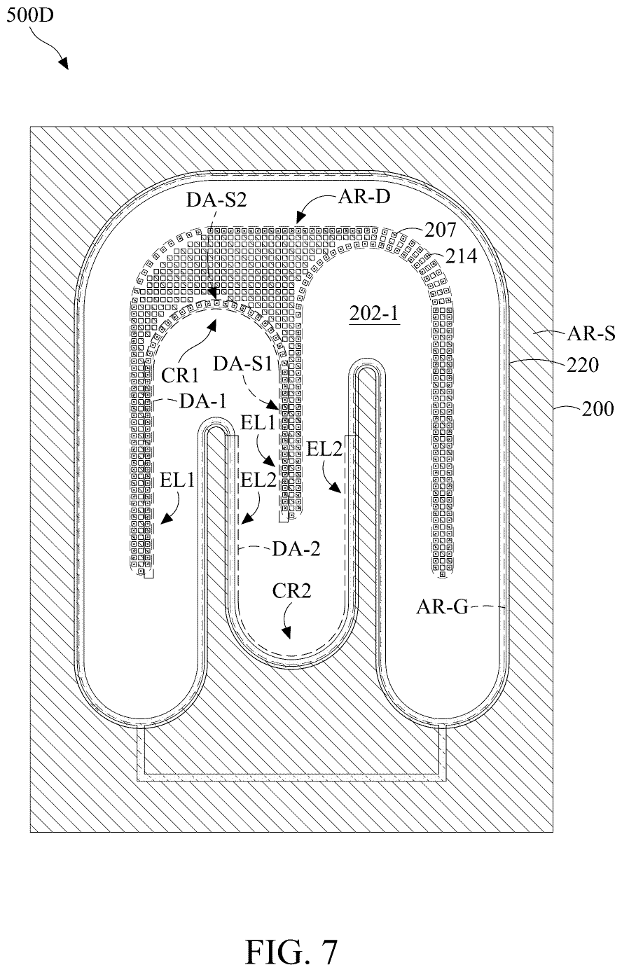

FIG. 7 is a schematic top view of a semiconductor device 500D in accordance with some embodiments of the disclosure, in which the reference numbers the same or similar to those in FIG. 1 denote the same or similar elements. As shown in FIG. 7, at least one of the differences between the semiconductor device 500D and the semiconductor device 500A is that the distribution region DA of the drain active region AR-D of the semiconductor device 500D may be interdigitated. Furthermore, the top view shapes of the gate active region AR-G, the source active region AR-S and the gate electrode 220 of the semiconductor device 500C may correspond to the top view shape (interdigital shape) of the distribution region DA. In order to make the drawing clear and easy to understand, the source contact, the bulk active region and the bulk contact are not shown in FIG. 7.

In this embodiment, the distribution region DA of the drain active region AR-D may be interdigitated. The first side DA-S1 of the U-shaped region DA-1 of the distribution region DA is located at the edge of the interdigitated distribution region DA. In addition, the second side DA-S2 of the distribution region DA is located at the middle portion of the interdigitated distribution region DA.

The gate active region AR-G may be interdigitated, and may have U-shaped regions DA-2. In this embodiment, the U-shaped regions DA-1 and the U-shaped regions DA-2 are arranged opposite to each other. Furthermore, the plurality of linear extension portions EL1 of the U-shaped region DA-1 are arranged staggered with the plurality of linear extension portions EL2 of the U-shaped region DA-2. The linear extension portions EL1 of the U-shaped regions DA-1 point to the rounded corners CR2 of the U-shaped regions DA-2. In addition, the linear extending portions EL2 of the U-shaped regions DA-2 point to the rounded corner portions CR1 of the U-shaped regions DA-1.

In some embodiments, the drain active segments 207 of the drain active regions AR-D of the semiconductor devices 500B, 500C, and 500D may have the shapes and arrangements as shown in FIGS. 3A to 3H, which will not be repeated here. The drain active segments 207 and the drain contacts 214 of the semiconductor devices 500B, 500C, and 500D may have a connection relationship as shown in FIGS. 4A to 4C, which will not be repeated here.

Embodiments provide a semiconductor device. The semiconductor device includes a substrate and drain contacts. The substrate has an active region. The active region includes a gate active region, a source active region and a drain active region. The source active region and the drain active region are located on opposite sides of the gate active region. The drain active region includes a drain active segments that are spaced apart from each other. The drain contacts are disposed on a portion of the drain active segments. The number of drain active segments is equal to a first number. The number of drain contacts is equal to a second number, and the first number is not equal to the second number.

In some embodiments, the first number is higher than the second number.

In some embodiments, the drain contacts are disposed on the second number of drain active segments, and the remaining drain active segments are electrically floating.

In some embodiments, a distribution region of the drain active segments includes a first U-shaped region.

In some embodiments, the first U-shaped region has a first side close to the gate active region and a second side away from the gate active region. The drain contacts are disposed on the drain active segments disposed the second side, but not disposed on the drain active segments close to the first side.

In some embodiments, the first U-shaped region has a first rounded corner portion and a first linear extension portion connected to the first rounded corner portion. The drain contacts are disposed on the drain active segments of the first linear extension portion, but not disposed on the drain active segments of the first rounded corner portion.

In some embodiments, the drain contacts are disposed on the drain active segments of the first linear extension away from the first rounded portion.

In some embodiments, the distribution region includes a ring shape or an interdigitated shape.

In some embodiments, when the distribution region is a ring-shaped distribution region, the first side is located outside the ring-shaped distribution region, and the second side is located inside the ring-shaped distribution region.

In some embodiments, when the distribution region is an interdigitated distribution region, the first side is located at an edge of the interdigitated distribution region, and the second side is located at a middle portion of the interdigitated distribution region.

In some embodiments, the gate active region is continuously distributed and has a second U-shaped region. The second U-shaped region is arranged corresponding to the first U-shaped region.

In some embodiments, the second U-shaped region is located outside and arranged parallel to the first U-shaped region.

In some embodiments, the second U-shaped region has a second rounded corner portion and a second linear extension portion connected to the second rounded corner portion. The first linear extension portion of the first U-shaped region is arranged staggered with the second linear extension portions of the second U-shaped region. The first linear extension portion of the first U-shaped region points to the second rounded corner portion of the second U-shaped region. The second linear extension portion of the second U-shaped region points to the first rounded corner portion of the first U-shaped region.

In some embodiments, a distribution region of the gate active region and a distribution region of the drain active segments have the same or similar shapes.

In some embodiments, the source active region is continuously distributed and has a third U-shaped region. The third U-shaped region is arranged corresponding to the second U-shaped region.

In some embodiments, the source active region surrounds the gate active region.

In some embodiments, the source active region is connected to the gate active region.

In some embodiments, the drain active segment includes a rectangular, circular, or oval shape.

In some embodiments, the drain active segments includes first drain active segments and second drain active segments. A first area of each of the first drain active segments is not equal to that a second area of each of the second drain active segments.

In some embodiments, the semiconductor device further includes a gate electrode, a source contact, a drain electrode, and a source electrode. The gate electrode is disposed on the gate active region. The source contact is electrically connected to the source active region. The drain electrode is electrically connected to the drain contacts. The source electrode is electrically connected to the source contact.

The semiconductor device in accordance with some embodiments of the disclosure includes a plurality of drain active segments that are laterally spaced apart from each other. The drain active segments may be used as the electrostatic discharge (ESD) protection component of the semiconductor device itself, and do not occupy the layout area of the semiconductor devices, which is conducive to the miniaturization of the size of the semiconductor devices. Moreover, the semiconductor device in accordance with some embodiments of the disclosure do not have the problem of the conventional electrostatic discharge protection component that is turned on more slowly than an initial-on semiconductor device. Moreover, these drain active segments of the semiconductor device may be used as small resistors, and are electrically connected to the drain electrode in parallel through their respective drain contacts, thereby spreading the electrostatic discharge current uniformly to enhance the ability of the semiconductor device of the present disclosure to withstand electrostatic discharge. Therefore, the semiconductor device of the present disclosure have better electrostatic discharge protection capability, which is conducive to the application for ultra-high voltage (UHV) devices. Furthermore, the drain contacts are only connected to the drain active segments located at the inner side (away from the gate electrode). Therefore, the number of drain contacts is less than the number of drain active segments. Compared with the drain active segments located at the outer side (close to the gate electrode), the drain active segments located at the inner side (away from the gate electrode) has a lower surface electric field. Therefore, when the electrostatic discharge event occurs, the above-mentioned The connection method may prevent the drain contacts disposed on the outer drain active segments from being invaded and burned out by electrostatic discharge current, further enhancing the ability of the semiconductor device to withstand electrostatic discharge.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate having an active region, wherein the active region comprises:
a gate active region; and
a source active region and a drain active region are located on opposite sides of the gate active region, wherein the drain active region comprises drain active segments that are spaced apart from each other; and
drain contacts disposed on a portion of the drain active segments, wherein the number of drain active segments is equal to a first number, the number of drain contacts is equal to a second number, and the first number is not equal to the second number.

2. The semiconductor device as claimed in claim 1, wherein the first number is higher than the second number.

3. The semiconductor device as claimed in claim 2, wherein the drain contacts are disposed on the second number of drain active segments, and the remaining drain active segments are electrically floating.

4. The semiconductor device as claimed in claim 1, wherein a distribution region of the drain active segments comprises a first U-shaped region.

5. The semiconductor device as claimed in claim 4, wherein the first U-shaped region has a first side close to the gate active region and a second side away from the gate active region, and the drain contacts are disposed on the drain active segments close to the second side but not disposed on the drain active segments close to the first side.

6. The semiconductor device as claimed in claim 5, wherein the first U-shaped region has a first rounded corner portion and a first linear extension portion connected to the first rounded corner portion, and the drain contacts are disposed on the drain active segments of the first linear extension portion but not disposed on the drain active segments of the first rounded corner portion.

7. The semiconductor device as claimed in claim 6, wherein the drain contacts are disposed on the drain active segments in the first linear extension away from the first rounded portion.

8. The semiconductor device as claimed in claim 6, wherein the distribution region comprises a ring shape or an interdigitated shape.

9. The semiconductor device as claimed in claim 8, wherein when the distribution region is a ring-shaped distribution region, the first side is located outside the ring-shaped distribution region, and the second side is located inside the ring-shaped distribution region.

10. The semiconductor device as claimed in claim 8, wherein when the distribution region is an interdigitated distribution region, the first side is located at an edge of the interdigitated distribution region, and the second side is located at a middle portion of the interdigitated distribution region.

11. The semiconductor device as claimed in claim 8, wherein the gate active region is continuously distributed and has a second U-shaped region, and the second U-shaped region is arranged corresponding to the first U-shaped region.

12. The semiconductor device as claimed in claim 11, wherein the second U-shaped region is located outside the first U-shaped region and is arranged parallel to the first U-shaped region.

13. The semiconductor device as claimed in claim 11, wherein the second U-shaped region has a second rounded corner portion and a second linear extension portion connected to the second rounded corner portion, and the first linear extension of the first U-shaped region is staggered with the second linear extension portion of the second U-shaped region, and wherein the first linear extension portion of the first U-shaped region points to the second rounded corner portion of the second U-shaped region, and the second linear extension portion of the second U-shaped region points to the first rounded corner portion of the first U-shaped region.

14. The semiconductor device as claimed in claim 11, wherein the gate active region and the distribution region of the drain active segments have the same or similar shape.

15. The semiconductor device as claimed in claim 11, wherein the source active region is continuously distributed and has a third U-shaped region, and the third U-shaped region is arranged corresponding to the second U-shaped region.

16. The semiconductor device as claimed in claim 15, wherein the source active region surrounds the gate active region.

17. The semiconductor device as claimed in claim 15, wherein the source active region is connected to the gate active region.

18. The semiconductor device as claimed in claim 1, wherein the drain active segments comprise a rectangular, circular or oval shape.

19. The semiconductor device as claimed in claim 1, wherein the drain active segments comprise first drain active segments and second drain active segments, and a first area of each of the first drain active segments is not equal to a second area of each of the second drain active segments.

20. The semiconductor device as claimed in claim 1, further comprising:
a gate electrode disposed on the gate active region;
a source contact electrically connected to the source active region;
a drain electrode electrically connected to the drain contacts; and
a source electrode electrically connected to the source contact.
